(19) United States
(12) Patent Application Publication
(10) Pub. No.: US 2024/0363602 A1
(43) Pub. Date: Oct. 31, 2024

(54) METHOD FOR TRANSFERRING OPTOELECTRONIC SEMICONDUCTOR COMPONENTS

(71) Applicant: ams-OSRAM International GmbH, Regensburg (DE)

(72) Inventors: Peter Stauss, Stephanskirchen (DE); Alexander Pfeuffer, Regensburg (DE)

(21) Appl. No.: 18/681,769

(22) PCT Filed: Aug. 3, 2022
(86) PCT No.: PCT/EP2022/071865

§ 371 Date: Feb. 6, 2024

(30) Foreign Application Priority Data
Aug. 9, 2021 (DE) 10 2021 120 689.8

(51) Int. Cl. H01L 25/13; H01L 33/00

(52) U.S. Cl. CPC H01L 25/13; H01L 33/005

(57) ABSTRACT

In an embodiment a method includes providing a plurality of optoelectronic semiconductor components on a first carrier, providing a second carrier comprising a contact structure with a plurality of periodically arranged contact surfaces on its top surface, accommodating the plurality of optoelectronic semiconductor components by a transfer unit including placing the transfer unit on a top surface of the optoelectronic semiconductor components opposite to the first carrier, lifting the plurality of optoelectronic semiconductor components from the first carrier, placing a first subset of the plurality of optoelectronic semiconductor components on a first subset of the plurality of periodically arranged contact surfaces and fixing the first subset of the plurality of optoelectronic semiconductor components on the first subset of the plurality of periodically arranged contact surfaces.

### CROSS-REFERENCE TO RELATED APPLICATIONS

This patent application is a national phase filing under section 371 of PCT/EP2022/071865, filed Aug. 3, 2022, which claims the priority of German patent application 10 2021 120 689.8, filed Aug. 9, 2021, each of which is incorporated herein by reference in its entirety.

### TECHNICAL FIELD

The present invention relates to a method for transferring optoelectronic semiconductor components from a first carrier to a second carrier. In particular, the present invention relates to a method for transferring optoelectronic semiconductor components from a first carrier to a second carrier and for creating an electrical and mechanical connection between the optoelectronic semiconductor components and the second carrier. Furthermore, the present invention relates to an optoelectronic device which is produced in particular by means of a method for transferring optoelectronic semiconductor components from a first carrier to a second carrier.

### BACKGROUND

For the production of displays, for example LED-or micro-LED-based displays, the LEDs or LED chips must be transferred from a donor substrate, for example the growth substrate of the LED chips, to a receiver substrate or target substrate (backplane). Due to the manufacturing process, the LEDs are usually arranged very densely on the donor substrate (dense chip pitch), whereas an arrangement of the LEDs with a specific and comparatively larger distance or pixel pitch may be desired on the target substrate.

To transfer the LEDs from the donor substrate to the target substrate, a stamp-based process is usually used that uses a large pick-and-place tool (transfer head or stamp) to pick up LEDs from the donor substrate and transfer them to the target substrate. However, the transfer head only picks up the LEDs from the donor substrate that match the specified pixel pattern on the target substrate. The greater the distance between the individual pixels, the fewer LEDs are transferred in one transfer cycle, given the specified size of the transfer head. For larger displays with large pixel pitches in particular, it is therefore necessary to move the transfer head very often and therefore over very long distances. However, this is very time-consuming and such a process is therefore comparatively expensive.

One approach to increasing the transfer rate and thus reducing costs would be to increase the speed of the transfer head and/or increase the size of the transfer head. However, such changes have a negative effect on the transfer performance and the placement accuracy of the LEDs.

### SUMMARY

Embodiments provide a method for transferring optoelectronic semiconductor components from a first carrier to a second carrier, by means of which the transfer rate when transferring optoelectronic semiconductor components from a first carrier to a second carrier can be increased in a simple and cost-effective manner and at the same time a reliable and positionally accurate transfer of the semiconductor components can be made possible.

A method according to embodiments of the invention for transferring optoelectronic semiconductor components from a first carrier to a second carrier comprises the steps of:
providing a plurality of optoelectronic semiconductor components on the first carrier;
providing the second carrier, wherein the second carrier comprises a contact structure with a plurality of periodically arranged contact surfaces on its top surface;
accommodating the plurality of optoelectronic semiconductor components by means of a transfer unit comprising placing the transfer unit on a top surface of the optoelectronic semiconductor components opposite the first carrier;
lifting the plurality of optoelectronic semiconductor components from the first substrate; and
placing a first subset of the plurality of optoelectronic semiconductor components on a first subset of the plurality of periodically arranged contact surfaces.

Embodiments of the invention provide using a transfer unit to lift a plurality of optoelectronic semiconductor components from a first carrier, in particular from a donor substrate or growth substrate of the optoelectronic semiconductor components, and, in a first step, to place only a first subset of optoelectronic semiconductor components from this plurality of optoelectronic semiconductor components on a second carrier, in particular a receiving substrate or target substrate (e.g. a backplane). In a second step, a second subset of the optoelectronic semiconductor components located on the transfer unit can then be placed on the second carrier without new optoelectronic semiconductor components having to be lifted off the first carrier by means of the transfer unit. This reduces the travel distance that must be covered by the transfer unit, and the time required to transfer the optoelectronic semiconductor components and the associated costs can be reduced.

For example, the transfer unit can be designed in such a way that all optoelectronic semiconductor components can be lifted off the first carrier at the same time. The transfer unit is then moved above the second carrier and the optoelectronic semiconductor components are gradually placed on the second carrier. However, only a subset of the optoelectronic semiconductor components, in particular a subset corresponding to a desired pixel pitch on the second carrier, is placed on the second carrier for each step-by-step deposition. For this purpose, the second carrier comprises a contact structure with a plurality of periodically arranged contact surfaces on its top surface. In particular, the periodically arranged contact surfaces are arranged on the second carrier corresponding to a desired pixel pitch. When the transfer unit is lowered, only the optoelectronic semiconductor components opposite a respective contact surface enter into a mechanical connection with the second carrier. As a result, only the optoelectronic semiconductor components that come into contact with a respective contact surface are detached from the transfer unit and placed on the second carrier.

After a first subset of the accommodated optoelectronic semiconductor components is placed on the second carrier, the transfer unit does not have to move back to the first carrier to pick up optoelectronic semiconductor components again, but the transfer unit can merely be realigned above the second carrier to place a second subset of optoelectronic semiconductor components still on the transfer unit on a corresponding second subset of contact surfaces on the second carrier. In this way, the second carrier can be gradually equipped with optoelectronic semiconductor components without the transfer unit having to be moved in the direction of the first carrier after each placement of optoelectronic semiconductor components in order to pick up optoelectronic semiconductor components again. In particular, the periodically arranged contact surfaces can thus be equipped step by step with optoelectronic semiconductor components corresponding to a desired pixel pitch on the second carrier. The time required to transfer the optoelectronic semiconductor components and the associated costs can thus be reduced.

The first subset of the plurality of optoelectronic semiconductor components placed in a first step on the second carrier, or on a first subset of contact surfaces on the second carrier, comprises in particular a number of optoelectronic semiconductor components greater than 1. Further, the first subset of the plurality of optoelectronic semiconductor components is a true subset of the plurality of optoelectronic semiconductor components. In other words, the first subset of the plurality of optoelectronic semiconductor components comprises fewer optoelectronic semiconductor components than the plurality of optoelectronic semiconductor components.

The first subset of the plurality of optoelectronic semiconductor components placed on the second carrier in a first step, or on a first subset of contact surfaces on the second carrier, may in particular comprise a number of optoelectronic semiconductor components corresponding to the number of contact surfaces of the first subset of contact surfaces on the second carrier. The number of the first subset of optoelectronic semiconductor components can correspond to the number of contact areas of the first subset of contact surfaces on the second carrier. In particular, one optoelectronic semiconductor component of each of the first subset of optoelectronic semiconductor components can thus be placed on a corresponding contact surface of each of the first subset of contact surfaces on the second carrier.

In some embodiments, the plurality of contact surfaces is each formed by a protrusion on the second carrier. Accordingly, when the transfer unit is lowered, only the optoelectronic semiconductor components come into contact with the second carrier and then enter into a mechanical connection with one another, which are opposite a respective protrusion. As a result, only the optoelectronic semiconductor components are detached from the transfer unit and placed on the second carrier, which come into contact with a respective protrusion.

In some embodiments, the plurality of contact surfaces is each formed by a cavity filled with a bonding layer in the second carrier. A top surface of the bonding layer can form a flat surface with the second carrier and can be introduced into the cavities by means of doctor blades, for example. The bonding layer may, for example, comprise an adhesive, a solder adhesive or a solder and may be configured to create a mechanical and/or electrical connection between the second carrier and the optoelectronic semiconductor components.

The transfer unit can be designed elastically in such a way that when the first subset of the plurality of optoelectronic semiconductor components is placed on the first subset of the plurality of periodically arranged contact surfaces, the optoelectronic semiconductor components which do not come into contact with a respective contact surface but with the second carrier are slightly pressed into the material of the transfer unit. On the one hand, this can prevent damage to the optoelectronic semiconductor components that are not to be placed, and on the other hand, sufficient contact pressure can be ensured between a respective contact surface and the optoelectronic semiconductor components that come into contact with a respective contact surface.

In some embodiments, the method further comprises fixing the first subset of the plurality of optoelectronic semiconductor components to the first subset of the plurality of periodically arranged contact surfaces.

In some embodiments, the optoelectronic semiconductor components of the plurality of optoelectronic semiconductor components each comprise a first contour on a bottom surface facing the contact structure, and the contact surfaces, in particular protrusions, of the plurality of periodically arranged contact surfaces, in particular protrusions, each comprise a second contour corresponding to the first contour on an top surface facing the optoelectronic semiconductor components. In this case, corresponding can be understood in particular to mean that the first contour and the second contour correspond to each other in a similar way to the lock-and-key principle. The lock-and-key principle describes the function or shape of two or more structures that must fit together spatially in order to fulfill a specific function. Correspondingly, it can also be understood to mean that the first contour and the second contour are similar to two corresponding puzzle pieces.

In some embodiments, opposing first and second contours interlock when the first subset of the plurality of optoelectronic semiconductor components is placed. In particular, at least opposing portions of the first and second contours interlock during placement of the first subset of the plurality of optoelectronic semiconductor components. In particular, when the first subset of the plurality of optoelectronic semiconductor components is placed, opposing partial regions of the first and second contours can interlock or have a centering effect with respect to one another in such a way that the optoelectronic semiconductor components are aligned or centered with respect to the contact surfaces, in particular protrusions, in a desired manner when they are placed on the contact surfaces.

In some embodiments, opposing first and second contours each comprise a common sliding plane corresponding to one another, wherein the sliding plane is inclined in particular with respect to the normal of the top surface of the second carrier. In particular, the first contours, i.e. the optoelectronic semiconductor components, each comprise a sliding plane on a bottom surface facing the contact structure which, when the transfer unit is lowered in the direction of the second carrier, lies in a sliding plane of the second contours from a time of contact between the optoelectronic semiconductor components and the contact surfaces, in particular protrusions. The sliding plane runs in particular at an angle to the normal of the top surface of the second carrier, whereby at an angle can be understood in particular to mean that the sliding plane deviates at an acute or obtuse angle from a line or plane that is perpendicular to the top surface of the second carrier.

In some embodiments, the step of placing the first subset of the plurality of optoelectronic semiconductor components comprises a step of:
aligning the transfer unit with respect to the second carrier in such a way that the first subset of the plurality of optoelectronic semiconductor components is arranged laterally offset with respect to the first subset of the plurality of periodically arranged contact surfaces, in particular protrusions;
lowering the transfer unit until contact is established between the first subset of the plurality of optoelectronic semiconductor components and the first subset of the plurality of periodically arranged contact surfaces, in particular protrusions; and
shearing off the first subset of the plurality of optoelectronic semiconductor components from the transfer unit by further lowering the transfer unit.

The transfer unit can be aligned relative to the second carrier in such a way that the first subset of the plurality of optoelectronic semiconductor components is laterally offset relative to the first subset of the plurality of periodically arranged contact surfaces, in particular protrusions, in particular laterally offset by at most the edge length of an optoelectronic semiconductor component.

The step of shearing off can be affected in particular by an inclined respective sliding plane of the first subset of the plurality of optoelectronic semiconductor components sliding off a respective sliding plane of the first subset of the plurality of periodically arranged contact surfaces, in particular protrusions. The step of shearing off can accordingly comprise a lateral displacement of the first subset of the plurality of optoelectronic semiconductor components relative to the transfer unit, as a result of which the optoelectronic semiconductor components can be torn off or sheared off from the transfer unit and thus detached.

In some embodiments, the step of shearing off the first subset of the plurality of optoelectronic semiconductor components may comprise at least partially converting the vertical lowering movement into a lateral movement of the first subset of the plurality of optoelectronic semiconductor components. The step of shearing off can accordingly comprise a lateral displacement of the first subset of the plurality of optoelectronic semiconductor components relative to the transfer unit, wherein the optoelectronic semiconductor components can be sheared off from the transfer unit and thus detached.

In some embodiments, the step of placing the first subset of the plurality of optoelectronic semiconductor components comprises a step of:
aligning the transfer unit with respect to the second carrier such that the first subset of the plurality of optoelectronic semiconductor components is arranged substantially directly opposite the first subset of the plurality of periodically arranged contact surfaces, in particular protrusions;
lowering the transfer unit until contact is made between the first subset of the plurality of optoelectronic semiconductor components and the first subset of the plurality of periodically arranged contact surfaces, in particular protrusions; and
shearing off the first subset of the plurality of optoelectronic semiconductor components from the transfer unit by laterally displacing the transfer unit.

The step of shearing off can be affected in particular by the fact that at least opposite partial regions of the first and second contours interlock when the first subset of the plurality of optoelectronic semiconductor components is placed and are thus fixed in the lateral direction, and the optoelectronic semiconductor components are torn off or sheared off from the transfer unit by a lateral displacement of the transfer unit.

In some embodiments, the step of fixing the first subset of the plurality of optoelectronic semiconductor components comprises pressing the optoelectronic semiconductor components onto the first subset of the plurality of periodically arranged contact surfaces. Optionally, the step of fixing the optoelectronic semiconductor components additionally comprises heating the optoelectronic semiconductor components. In particular, the step of fixing the optoelectronic semiconductor components can be performed according to the steps of a thermo-compression bonding (TCB) process.

In some embodiments, the second carrier is formed by a printed circuit board or backplane. In particular, the second carrier may be formed by a multilayer ceramic substrate, by a silicon wafer, or by a glass plate. In some embodiments, the second carrier may be formed with electrical connections thereon and may comprise, for example, thin film transistors.

The first carrier can, for example, be formed by a wafer or a growth substrate. The optoelectronic semiconductor components may, for example, have been grown on the first carrier. In particular, the plurality of optoelectronic semiconductor components can be grown on the first carrier and arranged at a distance of 2 μm to 3 μm, or a smaller distance from each other on the first carrier.

On the other hand, the first carrier can also be formed by an intermediate carrier, for example by a multilayer ceramic substrate, by a silicon wafer, or by a glass plate, on which the optoelectronic semiconductor components are arranged. There may also be a separating layer between the optoelectronic semiconductor components and the first carrier, which makes it easier to detach the optoelectronic semiconductor components from the first carrier.

In some embodiments, the optoelectronic semiconductor components comprise an optoelectronic light source. For example, the optoelectronic semiconductor components or the optoelectronic light sources may have an edge distance of less than 300 μm, in particular less than 150 μm. With these spatial dimensions, the optoelectronic semiconductor components or optoelectronic light sources are virtually invisible to the human eye.

In some embodiments, the optoelectronic semiconductor components each comprise an LED. The LED may in particular be referred to as a mini-LED, which is a small LED, for example with edge lengths of less than 200 μm, in particular up to less than 40 μm, in particular in the range from 200 μm to 10 μm. Another range is between 150 μm and 40 μm.

The LED may also be referred to as a micro LED, also known as a μLED, or a μLED chip, particularly in the case where the edge lengths are in the range of 70 μm to 3 μm. In some embodiments, the LED may have a spatial dimension of 90×150 μm or a spatial dimension of 75×125 μm.

In some embodiments, the mini-LED or μLED chip may be an unhoused semiconductor chip. Unhoused can mean that the chip comprises no housing around its semiconductor layers, such as a die. In some embodiments, unhoused may mean that the chip is free of any organic material. Thus, the unhoused device does not contain any organic compounds that contain carbon in covalent bonding.

In some embodiments, the optoelectronic semiconductor components are formed by a light source capable of emitting light of a particular color. In some embodiments, the optoelectronic semiconductor components may be configured to emit light of different colors such as red, green, blue and yellow. However, the optoelectronic semiconductor components may also be formed by a sensor, in particular a photosensitive sensor.

The optoelectronic semiconductor components can comprise electrical contact elements or contact surfaces for making electrical contact with the optoelectronic semiconductor components. For example, the optoelectronic semiconductor components can each comprise two electrical contact surfaces for making electrical contact with the optoelectronic semiconductor components. In one embodiment of the optoelectronic semiconductor components, the two electrical contact pads may be arranged on the same outer surface of the optoelectronic semiconductor components according to a flip-chip configuration, and in one embodiment of the optoelectronic semiconductor components, the two electrical contact pads may be arranged on opposite outer surfaces of the optoelectronic semiconductor components according to a vertically contactable component.

In some embodiments, the periodically arranged contact surfaces each comprise at least one contact pad for electrically contacting the optoelectronic semiconductor components. In particular, the periodically arranged contact surfaces each comprise one contact pad for electrically contacting the optoelectronic semiconductor components in the event that the optoelectronic semiconductor components comprise two electrical contact surfaces on opposite outer surfaces of the optoelectronic semiconductor components, whereas the periodically arranged contact surfaces each comprise two contact pads for making electrical contact with the optoelectronic semiconductor components in the event that the optoelectronic semiconductor components have two electrical contact surfaces on the same outer surface of the optoelectronic semiconductor components.

In some embodiments, the distance between the centers of respective adjacent contact surfaces on the second carrier corresponds to an in particular integer multiple of the distance between the centers of respective adjacent optoelectronic semiconductor components on the first carrier. In other words, the distance between the centers of adjacent contact surfaces or the pixel pitch corresponds in particular to an integer multiple of the distance between the centers of adjacent optoelectronic semiconductor components on the first carrier (chip pitch). The pixel pitch on the second carrier thus corresponds in particular to an integer multiple of the chip pitch of the optoelectronic semiconductor components on the first carrier. This can be particularly advantageous, since the optoelectronic semiconductor components, which are lifted from the first carrier by means of the transfer unit, are arranged on the transfer unit in accordance with the chip pitch and, due to the correlation between the pixel pitch on the second carrier and the chip pitch of the optoelectronic semiconductor components on the transfer unit, several optoelectronic semiconductor components can be placed simultaneously on the second carrier.

In some embodiments, the number of the plurality of optoelectronic semiconductor components that are lifted from the first carrier by the transfer unit is an integer multiple of the number of the first subset of the plurality of optoelectronic semiconductor components that are simultaneously placed on the second carrier in one step. This can be particularly advantageous, since in this way an equal number of the number of the first subset of optoelectronic semiconductor components can be placed on the second carrier in several steps until there are no more optoelectronic semiconductor components on the transfer unit. This means that no individual optoelectronic semiconductor components remain on the transfer unit.

In some embodiments, the method further comprises placing a second subset of the plurality of optoelectronic semiconductor components on a second subset of the plurality of periodically arranged contact surfaces. In particular, this step may follow the step of placing a first subset of the plurality of optoelectronic semiconductor components on a first subset of the plurality of periodically arranged contact surfaces.

In particular, the number of optoelectronic semiconductor components in the second subset may be equal to the number of optoelectronic semiconductor components in the first subset.

An optoelectronic device according to embodiments of the invention comprises:
a printed circuit board on the top surface of which a contact structure with a large number of periodically arranged protrusions is arranged;
a plurality of optoelectronic semiconductor components each arranged on one of the plurality of periodically arranged protrusions; and
wherein the optoelectronic semiconductor components each comprise a first contour on a bottom surface facing the contact structure, and the protrusions each comprise a second contour corresponding to the first contour on an top surface facing the optoelectronic semiconductor components.

In particular, the optoelectronic device may be an optoelectronic device manufactured by means of the aforementioned method.

In some embodiments, opposing first and second contours interlock or correspond to each other.

In some embodiments, the protrusions each comprise at least one contact pad for electrically contacting the optoelectronic semiconductor components. However, it is also possible that there is only a mechanical connection between the protrusions and the optoelectronic semiconductor components, and electrical contact surfaces of the optoelectronic semiconductor components are located on a side of the optoelectronic semiconductor components facing away from the protrusions.

In some embodiments, the second contours each comprise a connection from a first plane to a second plane that is vertically offset from the first plane. In particular, the second contours comprise a first plane and a second plane offset vertically with respect thereto, wherein the first and second planes extend substantially parallel to the top surface of the printed circuit board. Furthermore, the second contours comprise a connection that connects the first and second planes. The at least one contact pad can be arranged for each protrusion, in particular on the first or the second plane, and an optional second contact pad can be arranged on the other or the same plane. Furthermore, it is conceivable that the at least one contact pad is arranged on the connection between the first and the second plane, and it is also conceivable that the entire top surface of the protrusions or at least parts thereof is formed by a contact pad, for example in the form of a metallization.

In some embodiments, the second contour, in particular a connection of the second contour connecting a first plane and a second plane vertically offset therefrom, comprises at least one of the following shapes:
a truncated cone;
an inverse truncated cone;
a cone; and
an inclined plane;
or in cross section
a diagonal line;
an orbit;
areas of an orbit;
a parable; and
areas of a parabola such as half or only part of a parabola.

In some embodiments, the second contour is arranged outside the at least one contact pad or the at least one contact pad is arranged outside the second contour. The protrusions and the respectively associated at least one contact pad can in particular be formed by two separate and in particular different materials.

### BRIEF DESCRIPTION OF THE DRAWINGS

In the following, embodiments of the invention are explained in more detail with reference to the accompanying drawings.

FIG. 1 shows steps of a method for transferring optoelectronic semiconductor components from a first carrier to a second carrier in a cross-sectional view;

FIG. 2 shows steps of a method for transferring optoelectronic semiconductor components from a first carrier to a second carrier according to some aspects of the proposed principle in a cross-sectional view;

FIG. 3 shows a step of a method for transferring optoelectronic semiconductor components from a first carrier to a second carrier according to some aspects of the proposed principle in a cross-sectional view and two detailed views of the optoelectronic semiconductor components, as well as the contact surfaces or protrusions on which the optoelectronic semiconductor components are placed; and

FIGS. 4A and 4B show a plan view of a transfer unit and a plan view of a transfer unit according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

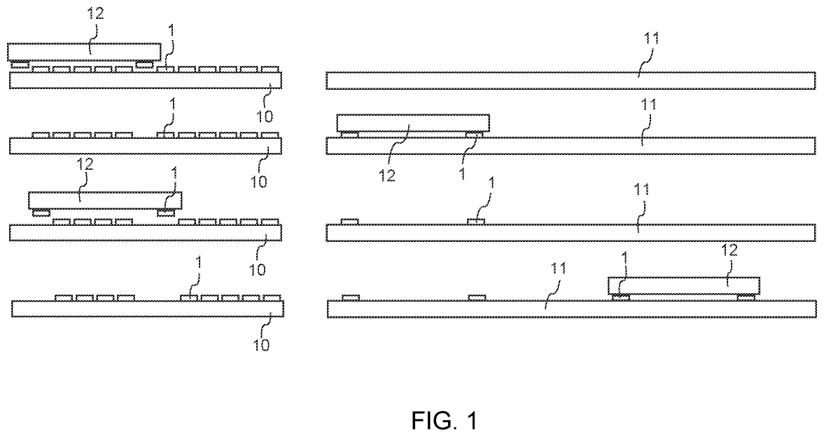

FIG. 1 shows steps of a method for transferring optoelectronic semiconductor components 1 from a first carrier 10 to a second carrier 11 in a cross-sectional view. In a first step, optoelectronic semiconductor components 1 are lifted from the first carrier 10 by means of a transfer unit 12. This is done by placing the transfer unit 12 on an top surface of the optoelectronic semiconductor components 1 opposite the first carrier 10, and the optoelectronic semiconductor components 1 are at least temporarily attached to the transfer unit, for example by means of a vacuum or an adhesive force.

The transfer unit 12 with the optoelectronic semiconductor components 1 adhering to it is then moved in the direction of the second carrier 11 and arranged opposite it in such a way that the optoelectronic semiconductor components 1 are opposite the second carrier 11. The optoelectronic semiconductor components 1 are then detached from the transfer unit 12 and arranged on the second carrier 11. In particular, the optoelectronic semiconductor components 1 are arranged on the second carrier 11 in such a way that they correlate with a pixel pitch provided on the second carrier 11.

After the optoelectronic semiconductor components 1 are arranged on the second carrier 11, the transfer unit 12 moves back in the direction of the first carrier 10 and picks up optoelectronic semiconductor components 1 from the first carrier 10 again. These are then transferred again to the second carrier 11 according to a desired positioning.

In particular, the transfer unit 12 is used to lift precisely those optoelectronic semiconductor components 1 from the first carrier 10 that correlate with a pixel pattern or pixel pitch provided on the second carrier 11. The greater the distance between the individual pixels, the fewer optoelectronic semiconductor components 1 are transferred in one transfer cycle, given the predetermined size of the transfer unit 12.

As a result of the method described, it is therefore necessary to move the transfer unit 12 very often from the first carrier 10 to the second carrier 11 and thus over very long distances, especially if there are many optoelectronic semiconductor components 1 to be transferred. This is very time-consuming and accordingly such a process is comparatively expensive.

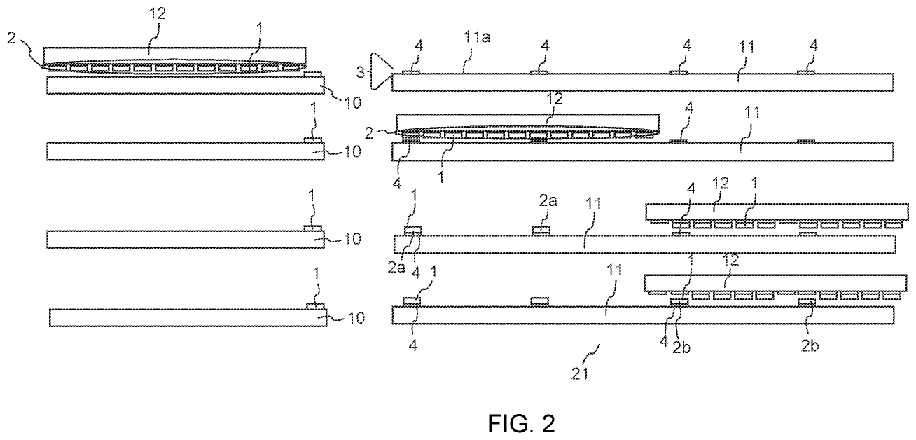

FIG. 2 therefore shows the steps of an improved method for transferring optoelectronic semiconductor components 1 from a first carrier 10 to a second carrier 11 according to some aspects of the proposed principle.

By means of the transfer unit 12, in comparison with the method shown in FIG. 1, not only the optoelectronic semiconductor components 1 are lifted off the first carrier 10, which are also placed on the second carrier 11 in a common step, but a plurality 2 of optoelectronic semiconductor components 1 is lifted off the carrier 11, which is greater than the number of optoelectronic semiconductor components 1 which are simultaneously placed on the second carrier 11.

The transfer unit 12 with the optoelectronic semiconductor components 1 adhering to it is then moved in the direction of the second carrier 11 and arranged opposite it in such a way that the optoelectronic semiconductor components 1 are opposite a contact structure 3 arranged on the second carrier 11.

On its top surface 11a, the second carrier 11 comprises the contact structure 3 with a large number of periodically arranged contact surfaces or, in the case shown, protrusions 4. In particular, the protrusions 4 are arranged in such a way that they correlate with a pixel pattern or pixel pitch provided on the second carrier 11. Furthermore, the protrusions each comprise at least one contact pad for making electrical contact with the optoelectronic semiconductor components 1.

Subsequently, a first subset 2a of the plurality 2 of optoelectronic semiconductor components 1 is placed on a first subset of the plurality of periodically arranged protrusions 4. For this purpose, the transfer unit 12 is lowered at a corresponding position in the direction of the second carrier 11 and the optoelectronic semiconductor components 1 which come into contact with opposite protrusions are detached from the transfer unit 12, placed on the protrusions 4 and fixed on the protrusions 4. Accordingly, the optoelectronic semiconductor components 1 of the first subset 2a are arranged on the second carrier 11 in such a way that they correlate with the pixel pitch provided on the second carrier 11.

After the first subset 2a of optoelectronic semiconductor components 1 is arranged on the protrusions 4 on the second carrier 11, the transfer unit 12 does not need to be moved back towards the first carrier 10, but can merely be repositioned over the second carrier 11 to place a second subset 2b of the plurality 2 of optoelectronic semiconductor components 1 on a second subset of the plurality of periodically arranged protrusions 4. This procedure can be repeated until the plurality 2 of optoelectronic semiconductor components 1 located on the transfer unit 12 have been placed on protrusions 4 on the second carrier 11. This reduces the travel distance that must be covered by the transfer unit 12, and the time required to transfer the optoelectronic semiconductor components 1 and the associated costs can be reduced.

An optoelectronic device 21 provided by such a method is shown in the bottom right of FIG. 2.

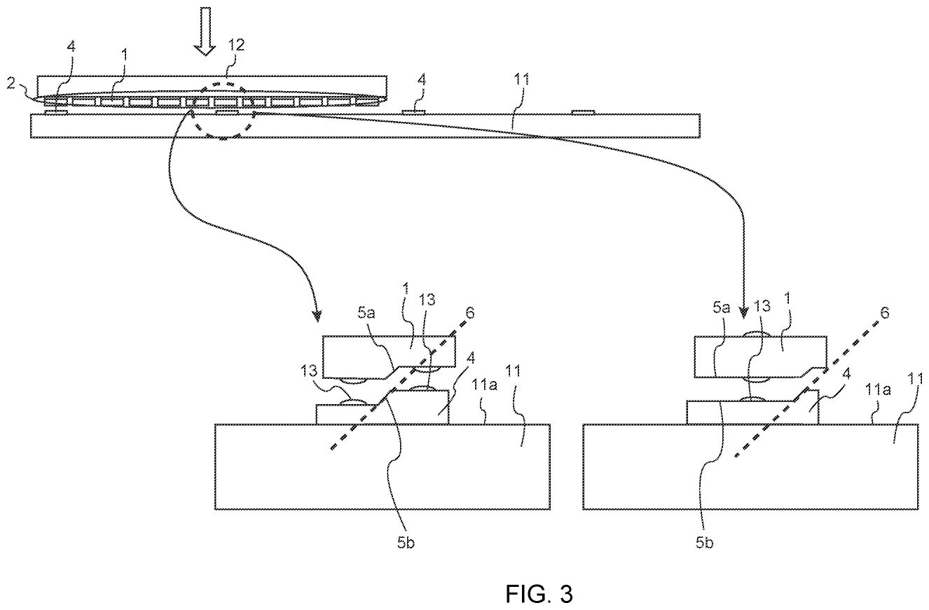

FIG. 3 shows a step of the method shown in FIG. 2 for transferring optoelectronic semiconductor components from a first carrier to a second carrier, in particular a printed circuit board 11, as well as two detailed views of the optoelectronic semiconductor components 1 and the protrusions 4 on which the optoelectronic semiconductor components 1 are placed.

The step of placing the first subset 2a of optoelectronic semiconductor components 1 on the first subset 2a of the plurality of periodically arranged protrusions 4 is shown. As can be seen from the two detailed views, the optoelectronic semiconductor component 1 shown by way of example in each case comprise a first contour 5a on a bottom surface facing the protrusion 4, and the protrusion 4 shown by way of example in each case comprise a second contour 5b corresponding to the first contour 5a on an top surface facing the optoelectronic semiconductor component. In particular, the first contour 5a and the second contour 5b are formed similarly to two corresponding puzzle pieces.

The opposing first and second contours 5a, 5b comprise a common sliding plane 6, which is inclined relative to the normal of the top surface 11a of the second carrier 11. The first contour 5a or the optoelectronic semiconductor component 1 also comprise, on a bottom surface facing the protrusion 4, a sliding plane, in particular also running at an angle, which lies in the sliding plane 6 when the transfer unit 12 is lowered in the direction of the second carrier 11, from a time of contact between the optoelectronic semiconductor component 1 and the protrusion 4.

In order to place the optoelectronic semiconductor components 1 on the first subset 2a of the plurality of periodically arranged protrusions 4, the transfer unit 12, as shown in FIG. 3, is aligned relative to the second carrier 11 in a first step in such a way that the first subset 2a of the plurality of optoelectronic semiconductor components 1 is arranged laterally offset relative to the first subset of the plurality of periodically arranged protrusions 4. The transfer unit 12 can be aligned with respect to the second carrier 11 in such a way that the first subset 2a of optoelectronic semiconductor components 1 is laterally offset with respect to the first subset of the plurality of periodically arranged protrusions 4, in particular laterally offset by only a few μm.

The transfer unit 12 is then lowered until contact is made between the first subset 2a of optoelectronic semiconductor components 1 and the protrusions 4. Opposite first and second contours 5a, 5b interlock accordingly at a certain point in time when the first subset 2a of optoelectronic semiconductor components 1 is lowered.

By lowering or further lowering the transfer unit 12, and by the interlocking of opposing first and second contours 5a, 5b, the first subset 2a of the plurality 2 of optoelectronic semiconductor components 1 is sheared off the transfer unit. This can be achieved in particular by the sliding plane of each of the optoelectronic semiconductor components 1 or the first contours 5a sliding along the common inclined sliding plane 6. Accordingly, the optoelectronic semiconductor components 1 are torn off the transfer unit 12 by a lateral displacement of the optoelectronic semiconductor components 1 relative to the transfer unit 12 and thus detached from the transfer unit 12.

The vertical lowering movement of the transfer unit 12 is converted into a lateral movement of the first subset 2a of optoelectronic semiconductor components 1 by the sliding of the optoelectronic semiconductor components 1 on the common inclined sliding plane 6 in each case. This results, with the lateral position of the transfer unit 12 held constant, in a lateral displacement of the first subset 2a of optoelectronic semiconductor components 1 relative to the transfer unit 12, as a result of which the optoelectronic semiconductor components 1 can be sheared off the transfer unit 12 and thus detached.

As shown in FIG. 3 or the detailed views of FIG. 3, the first and second contours 5a, 5b each comprise a first plane and a second plane offset vertically thereto, the first and second planes running substantially parallel to the top surface 11a of the printed circuit board 11. Furthermore, the first and second contours 5a, 5b each have a connection that connects the first and second planes to one another. These two connections each form a sliding plane of the first and second contours 5a, 5b respectively, wherein the sliding planes of the second contours 5b simultaneously also define the sliding planes 6.

The detailed view shown on the left in FIG. 3 also shows an embodiment in which the optoelectronic semiconductor component 1 comprises two electrical contact surfaces for making electrical contact with the optoelectronic semiconductor component 1, the two electrical contact surfaces being arranged on the same outer surface of the optoelectronic semiconductor component in accordance with a flip-chip configuration. The corresponding protrusion 4 accordingly comprises two contact pads 13 for making electrical contact with the optoelectronic semiconductor component 1.

The detailed view shown on the right in FIG. 3 shows an embodiment in which the optoelectronic semiconductor component 1 comprises two electrical contact surfaces on opposite outer surfaces of the optoelectronic semiconductor component 1 corresponding to a vertically contactable component. The corresponding protrusion 4 accordingly comprises a contact pad 13 for making electrical contact with the optoelectronic semiconductor component 1.

One or both of the contact pads 13 on the protrusion 4 are arranged in particular on the first or second plane and not in the area of the sliding plane 6.

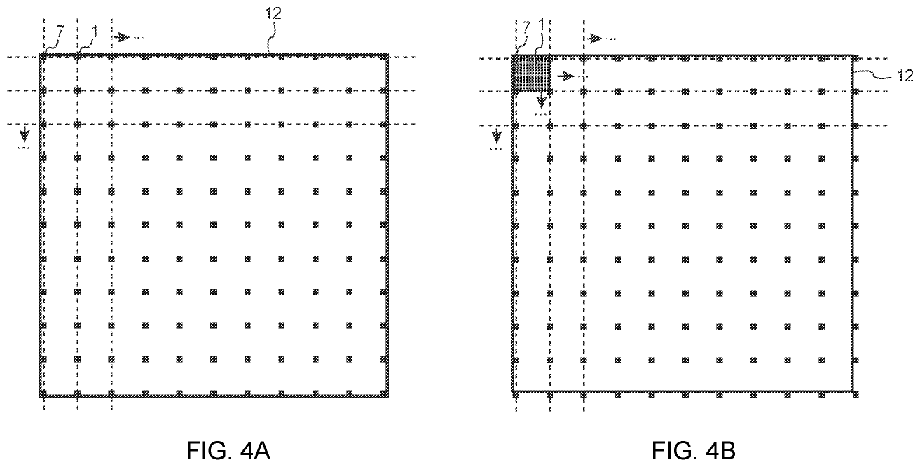

FIG. 4A shows a plan view of a transfer unit 12 used, for example, for a method as shown in FIG. 1. FIG. 4B, on the other hand, shows a top view of a transfer unit 12 that can be used for a method according to some aspects of the proposed principle.

A transfer unit 12 fitted with optoelectronic semiconductor components 1 is shown in each case, as well as a pixel pattern or pixel pitch 7 in which the optoelectronic semiconductor components 1 are to be placed on a second carrier.

By means of the transfer unit 12 shown in FIG. 4A, only the optoelectronic semiconductor components 1 correlating with the pixel pitch 7 were picked up from a first carrier, whereas by means of the transfer unit 12 shown in FIG. 4B, a region of optoelectronic semiconductor components 1 filling the transfer unit 12 and arranged in a corresponding chip pitch on a first carrier was picked up.

If the optoelectronic semiconductor components 1 picked up are now transferred to the second carrier by means of the transfer unit 12 shown in FIG. 4A, optoelectronic semiconductor components 1 must first be picked up again by means of the transfer unit before further optoelectronic semiconductor components 1 can be transferred to the second carrier.

By means of the transfer unit 12 shown in FIG. 4B, however, a first subset of the optoelectronic semiconductor components 1 can be transferred to the second carrier and the transfer unit 12 can then be repositioned merely above the second carrier so that a second, third, . . . etc. subset of the optoelectronic semiconductor components 1 can be transferred to the second carrier. This can be done until either the second carrier is fully loaded with optoelectronic semiconductor components 1 or there are no more optoelectronic semiconductor components 1 on the transfer unit 12.

In the case of the transfer unit 12 shown in FIG. 4B, the pixel pitch of the pixel pitch 7 corresponds in particular to a multiple of the distance between the centers of respectively adjacent optoelectronic semiconductor components 1 on the first carrier or on the transfer unit 12. The pixel pitch 7 thus corresponds to a multiple of the chip pitch of the optoelectronic semiconductor components 1 on the first carrier or on the transfer unit 12. This can be particularly advantageous, since the optoelectronic semiconductor components 1, which are lifted off the first carrier by means of the transfer unit 12, are arranged on the transfer unit 12 according to the chip pitch and, due to the correlation between the pixel pitch 7 and the chip pitch of the optoelectronic semiconductor components 1 on the transfer unit 12, several optoelectronic semiconductor components can be placed simultaneously on the second carrier 11 according to the pixel pitch. At the same time, this has the advantage that the transfer unit 12 for placing a second subset of optoelectronic semiconductor components 1 only has to be arranged laterally displaced by a chip pitch above protrusions that are not yet occupied in order to place the second subset of optoelectronic semiconductor components 1 on the free protrusions.

1.-21. (canceled)

22. A method comprising:
providing a plurality of optoelectronic semiconductor components on a first carrier;
providing a second carrier comprising a contact structure with a plurality of periodically arranged contact surfaces on its top surface;
accommodating the plurality of optoelectronic semiconductor components by a transfer unit comprising placing the transfer unit on a top surface of the optoelectronic semiconductor components opposite to the first carrier;
lifting the plurality of optoelectronic semiconductor components from the first carrier;
placing a first subset of the plurality of optoelectronic semiconductor components on a first subset of the plurality of periodically arranged contact surfaces; and
fixing the first subset of the plurality of optoelectronic semiconductor components on the first subset of the plurality of periodically arranged contact surfaces,
wherein each of the plurality of optoelectronic semiconductor components comprises a first contour on a bottom surface facing the contact structure, and
wherein each of the plurality of periodically arranged contact surfaces comprises a second contour corresponding to the first contour on an top surface facing the optoelectronic semiconductor components, and
wherein each of opposing first and second contours comprises a common sliding plane corresponding to one another, wherein the sliding plane extends inclined with respect to a normal of the top surface of the second carrier.

23. The method according to claim 22, wherein each of the periodically arranged contact surfaces is formed by a protrusion.

24. The method according to claim 22, wherein opposing first and second contours interlock when placing the first subset of the plurality of optoelectronic semiconductor components.

25. The method according to claim 22, wherein placing the first subset of the plurality of optoelectronic semiconductor components comprises:
aligning the transfer unit relative to the second carrier such that the first subset of the plurality of optoelectronic semiconductor components is arranged laterally offset relative to the first subset of the plurality of periodically arranged contact surfaces,
lowering the transfer unit until contact is established between the first subset of the plurality of optoelectronic semiconductor components and the first subset of the plurality of periodically arranged contact surfaces, and
shearing the first subset of the plurality of optoelectronic semiconductor components from the transfer unit by further lowering the transfer unit.

26. The method according to claim 25, wherein shearing is effected by a respective inclined extending sliding plane of the first subset of the plurality of optoelectronic semiconductor components sliding on a respective sliding plane of the first subset of the plurality of periodically arranged contact surfaces.

27. The method according to claim 25, wherein shearing comprises laterally displacing the first subset of the plurality of optoelectronic semiconductor components relative to the transfer unit.

28. The method according to claim 25, wherein shearing the first subset of the plurality of optoelectronic semiconductor components comprises at least partially converting a vertical lowering movement into a lateral movement of the first subset of the plurality of optoelectronic semiconductor components.

29. The method according to claim 22, further comprising fixing the first subset of the plurality of optoelectronic semiconductor components on the first subset of the plurality of periodically arranged contact surfaces, wherein fixing comprises pressing the optoelectronic semiconductor components onto the first subset of the plurality of periodically arranged contact surfaces and optionally heating the optoelectronic semiconductor components.

30. The method according to claim 22, wherein the second carrier is a printed circuit board.

31. The method according to claim 22, wherein each of the periodically arranged contact surfaces comprises at least one contact pad for making electrical contact with the optoelectronic semiconductor components.

32. The method according to claim 22, wherein a distance between centers of respectively adjacent contact surfaces on the second carrier corresponds to a multiple of a distance between centers of respectively adjacent optoelectronic semiconductor components on the first carrier.

33. The method according to claim 22, wherein a number of the plurality of optoelectronic semiconductor components corresponds to an integer multiple of a number of the first subset of the plurality of optoelectronic semiconductor components.

34. The method according to claim 22, further comprising placing a second subset of the plurality of optoelectronic semiconductor components on a second subset of the plurality of periodically arranged contact pads.

35. The method according to claim 34, wherein a number of optoelectronic semiconductor components in the second subset is equal to a number of optoelectronic semiconductor components in the first subset.

36. An optoelectronic device comprising:
a printed circuit board on a top surface of which a contact structure with a plurality of periodically arranged protrusions is arranged; and
a plurality of optoelectronic semiconductor components, each of the plurality of semiconductor components disposed on one of the plurality of periodically arranged protrusions,
wherein each of the optoelectronic semiconductor components comprises a first contour on a bottom surface facing the contact structure,
wherein each of the protrusions each comprises a second contour corresponding to the first contour on a top surface facing the optoelectronic semiconductor components, and
wherein each of the second contours comprises a connection from a first plane to a second plane vertically offset from the first plane.

37. The optoelectronic device according to claim 36, wherein opposing first and second contours interlock with each other.

38. The optoelectronic device according to claim 36, wherein each of the protrusions comprises at least one contact pad configured to electrically contact the optoelectronic semiconductor components.

39. The optoelectronic device according to claim 38, wherein the second contour is arranged outside the at least one contact pad.

40. The optoelectronic device according to claim 36, wherein the second contours comprise at least one of the following shapes:
truncated cone;
inverse truncated cone;
cone;
inclined plane;
orbit;
parabola; or
areas of a parabola.
